(19) United States
(12) Patent Application Publication
(10) Pub. No.: US 2007/0273025 A1
(43) Pub. Date: Nov. 29, 2007

(54) Device Comprising Circuit Elements Connected By Bonding Bump Structure

(75) Inventor: Joseph Bellaiche, Fontenay-Sous-Bois (FR)

Correspondence Address: PHILIPS ELECTRONICS NORTH AMERICA CORPORATION;INTELLECTUAL PROPERTY & STANDARDS, 370 W. TRIMBLE ROAD MS 91/MG, SAN JOSE, CA, 95131, US

(73) Assignee: KONINKLIJKE PHILIPS ELECTRONICS N.V., Eindhoven (NL)

(21) Appl. No.: 10/561,577

(22) PCT Filed: Oct. 31, 2003
(86) PCT No.: PCT/IB04/04900

§ 371 Date: Mar. 12, 2007

(30) Foreign Application Priority Data
Nov. 6, 2002 (EP) 02292766.9

(51) Int. Cl. H01L 23/48; H01L 21/44; H01L 21/46

(52) U.S. Cl. 257/737; 438/455; 438/614; 257/E23.01; 257/E21.476; 257/E21.482

(57) ABSTRACT

A bonding-bump (1) of small dimensions comprises a gold pedestal portion (2) formed on a circuit element (10), a nickel barrier layer (3) formed on the pedestal portion (2), and a soldering portion (5) formed on the barrier layer (3). The soldering portion (5) comprises first (6) and second (8) gold layers having an intermediate tin layer (7) sandwiched therebetween. The relative masses of gold and tin in the first, second and intermediate layers (6-8) gives the soldering portion (5) a composition corresponding to the eutectic gold-tin composition. The bonding-bump (1) may be manufactured by depositing a titanium seed layer onto the circuit element (10), removing portions of the titanium layer where there are contact pads (P) on the circuit element (10), electroplating the layers and portions (2-8) constituting the bonding-bump (1), and removing the remaining portions of the seed layer. This bonding-bond technique is used to connect circuit elements in electronic devices. Such electronic devices are appropriate to be used in telecommunications, for instance in mobile terminals.

### FIELD OF THE INVENTION

The present invention relates to the field of bump-bonding and, more particularly, to a new bonding-bump structure, to a method of forming the new bonding-bump structure, to a method of using the new bonding-bump structure to connect two circuit elements, and to a device comprising circuits elements connected by said bonding-bump structure. The invention finds a particular application in the field of telecommunications, for manufacturing mobile terminals.

It is to be understood that the expression “circuit element” is used in the present document in a broad sense, and in particular it encompasses packaging substrates and the like, as well as elements bearing active components. The present invention provides particular advantages when applied in the field of bonding microwave circuit elements. Connecting circuits using bonding-bump structure is already known from the patent EP 1 024 531. This patent relates to circuits operating at microwave frequencies. These circuits are becoming used to an increasing extent in consumer products. A major component of many microwave circuits is the monolithic microwave integrated circuit denoted by MMIC. This integrated circuit has all of the active circuitry on one face thereof, termed “the active face”. When connecting MMICs to other elements, for example, when mounting the MMIC on a substrate, care must be taken to ensure that parasitic capacitance and inductance are low. This favours the use of bump-bonding techniques.

In bump-bonding techniques, bumps made of a conductive material are formed on contact pads on the first circuit element, for example, the MMIC, then this first circuit element is brought into a facing relationship with a second circuit element, typically a mounting substrate, such as a circuit board, so that the bumps are aligned with respective conductive traces or pads on the second circuit element. The first and second circuit elements are brought together, and bonding is caused either by application of pressure or, more usually, by heating until the bump material melts (which generally involves application of a temperature of 320° C. for 10-20 seconds).

Conventionally, bumps used for bonding are spherical or hemispherical. However, it has also been proposed to provide a hemispherical bump, or multi-layer bump, at the top of a column, the column being used to ensure a certain minimum spacing between the bonded circuit elements.

As the degree of circuit integration becomes ever higher, the density of packing of conductive traces/pads on circuit elements such as MMICs becomes correspondingly higher. It is thus important that the dimensions of bonding-bumps should be sufficiently low to avoid accidental interconnection of two neighbouring conductors/contact pads. Known bump-bonding techniques do not always allow bumps of sufficiently small dimensions to be formed.

Furthermore, the techniques used to form bonding-bumps can result in severe deterioration of the properties of the circuit element upon which the bumps are formed. They can create defects in the substrate of said circuit element, for instance a semiconductor substrate, which defects can further propagate in the layers of the circuit on the substrate. Also, only one failing bonding-bump in a device can completely prevent the device from working. Hence, the bonding step is a very delicate operation.

In view of the above disadvantages, the present invention seeks to provide an improved bonding-bump structure that has small dimensions and which has a method of fabrication that enables the properties of the underlying circuit element to be preserved.

More particularly, the present invention provides a bonding-bump structure comprising: a pedestal portion comprising gold and formed on a circuit element; a barrier layer formed on the pedestal portion; a soldering portion formed on the barrier layer, the soldering portion comprising a first layer comprising gold, a second layer comprising gold and an intermediate layer comprising tin and located between the first and second layers; wherein the relative masses of gold and tin in the soldering portion are such that the composition of the soldering portion corresponds to the eutectic gold-tin composition.

Use of the bonding-bump structure according to the present invention enables all contacts of a circuit element to be bonded at once. Moreover, when the bonding-bump structure of the present invention is used for bonding microwave circuit elements it results in low parasitic inductance and the circuit element's thermal resistance may be improved.

Typically, the pedestal portion of the bonding-bump has a height of the order of 30 μm. It is advantageous for the barrier layer to have a thickness of the order of 0.2 μm. Various metals which are capable of being deposited by electroplating may be used to form the barrier layer; however an excellent material for this purpose is Ni.

In order to ensure that the composition of the soldering portion corresponds to the eutectic gold-tin composition it is advantageous that the first layer should be a gold layer having a thickness from 1.0 to 1.3 μm , the second layer should be a gold layer having a thickness from 0.7 to 0.8 μm, and the intermediate layer should be a layer of tin having a thickness in the range from 1.5 to 1.8 μm. Preferably the first layer made of gold should be approximately 1.15 μm thick, the second layer made of gold should be approximately 0.75 ∥m thick and the intermediate tin layer should be approximately 1.65 μm thick.

Using the bonding-bump structure described above it is possible to form bonding-bumps of extremely small dimensions, notably having a height of the order of 35 μm and a diameter of the order of 60 μm.

The bonding-bumps having the above-described structure are particularly well-suited for use in bump-bonding MMICs to other circuit elements.

The present invention further provides a method of forming the above-described bonding-bumps, and a method of connecting a first and second circuit element using such bonding-bumps

The above and other features, functions and advantages of the present invention will become clearer from the following detailed description of preferred embodiments thereof, given by way of example, and illustrated by the accompanying drawings, in which:

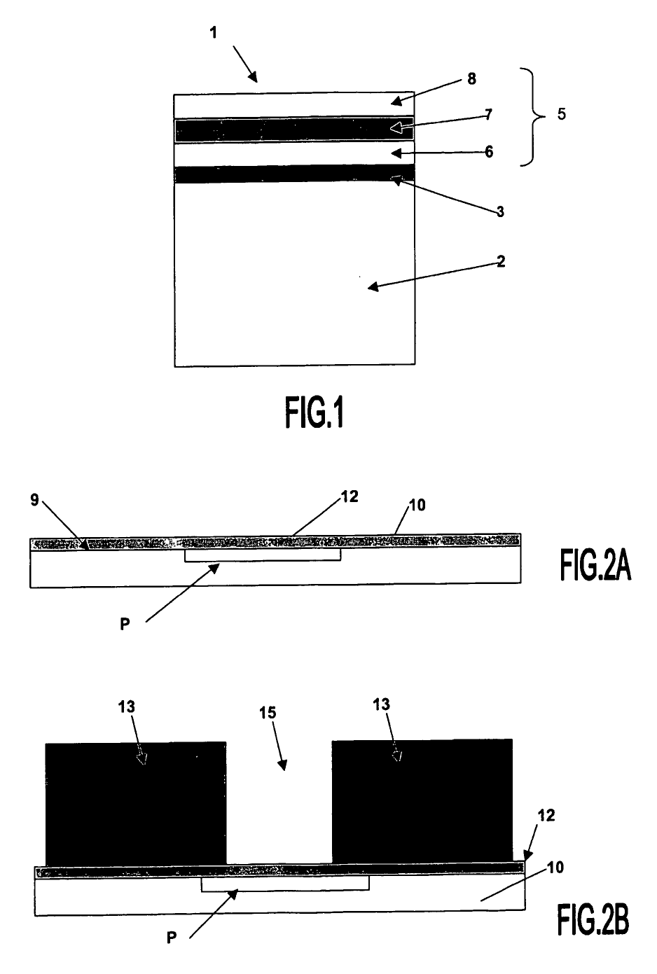

FIG. 1 shows schematically the structure of a bonding-bump according to a preferred embodiment of the invention;

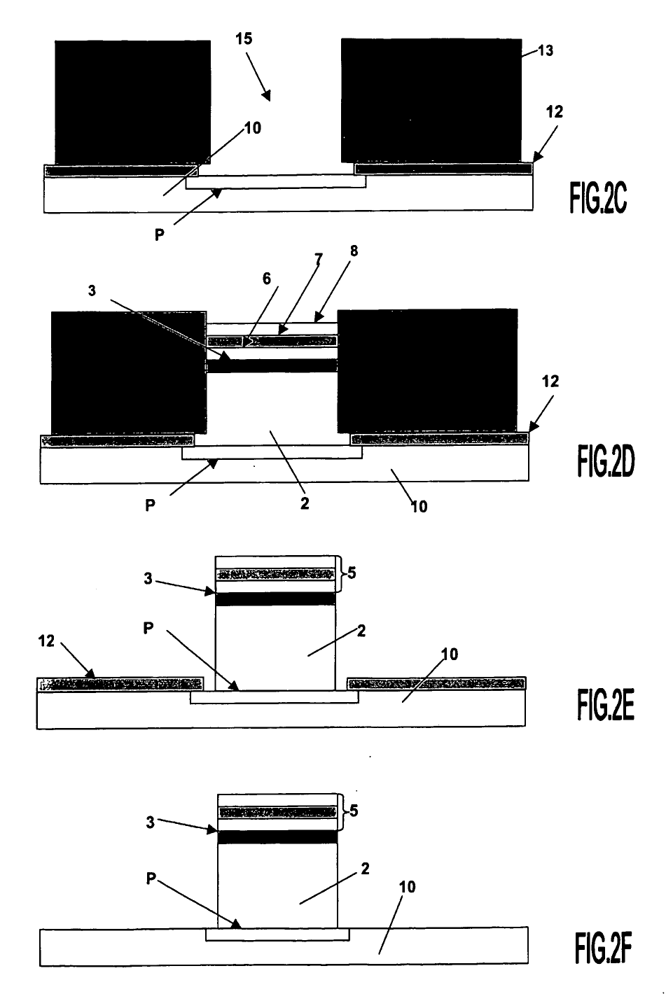

FIG. 2 illustrates the various steps involved in fabrication of the bonding-bump structure of FIG. 1 according to a preferred method; and

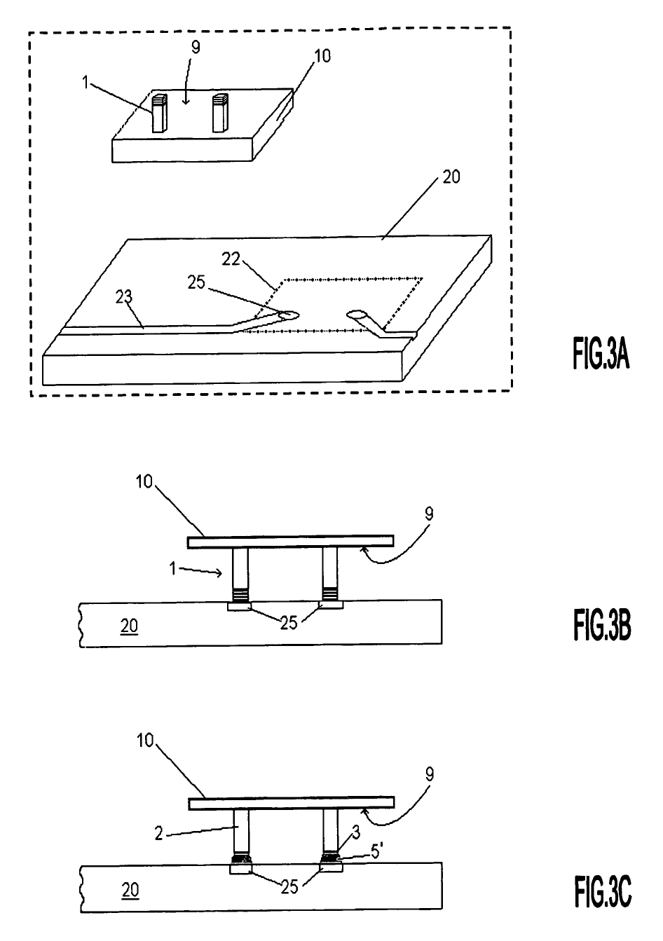

FIG. 3 illustrates the various steps involved in a preferred bump-bonding method for connecting two circuit elements using the bonding-bump structure of the preferred embodiment of the invention.

A preferred embodiment of bonding-bump structure according to the present invention will now be described with reference to FIG. 1.

According to the preferred embodiment, a bonding-bump 1 according to the present invention comprises a column or pedestal 2 made of gold (Au), a barrier layer 3 made of nickel (Ni), and a soldering portion 5 having a multi-layer structure. The Au column 2 preferably has a height from 25 to 35 μm (for example, 30 μm) in order to facilitate the associated lithography process, in particular to maintain the integrity of the photoresist during electroplating of the column 2, and a diameter from 55 to 65 μm (for example, 50 μm). The Ni barrier layer 3 preferably is very thin, of the order of 0.2 μm. However, the presence of the Ni layer 3 is important because it separates the Au column 2 from the soldering portion 5, ensuring that the Au column 2 is not involved in the soldering process when the bonding-bump is used.

Advantageously, the soldering portion 5 consists of a sandwich of a lower Au layer 6, an intermediate tin (Sn) layer 7 and a top Au layer 8. Preferably all of these metallic layers are pure (purity of ≧99.9%) in order to ensure a suitable degree of reliability. The dimensions of the layers 6, 7 and 8 making up the soldering portion 5 are selected such that the relative masses of Au and Sn in the soldering portion 5 considered as a whole correspond to the eutectic Au—Sn composition, that is a composition having a low and reliably-reproducible melting point (280° C.). By providing the top of the bump 1 with a soldering portion S having a sandwich structure corresponding to the eutectic Au—Sn composition, it becomes possible to perform bump bonding at a relatively low temperature, thus avoiding damage to the circuit elements being connected.

The preferred dimensions of the layers 6, 7 and 8 are, as follows:

| | |
|---|---|
| first Au layer (6) | from 1.0 to 1.3 μm, |
| intermediate Sn layer (7): | from 1.5 to 1.8 μm and |
| second Au layer (8): | from 0.7 to 0.8 μm,. |

However, it is to be understood that other dimensions can be used provided that they enable the multi-layer solder portion 5 to correspond to the eutectic composition.

The preferred method of forming the bonding-bump structure of FIG. 1 will now be described with reference to FIG. 2. In this description it is assumed that a single bonding-bump 1 is being formed on the active surface 9 of an MMIC 10. This active surface 9 has a contact pad P which is to be used for connecting the MMIC 10 to another circuit element via the bonding-bump 1. (Of course, in practice, an MMIC would have a large number of contact pads and bonding-bumps 1 could be formed for all of these pads P simultaneously.)

Referring to FIG. 2A, on the active surface 9 of the MMIC 10, a layer of titanium (Ti) 12 is deposited by any suitable technique (sputtering, physical vapour deposition, etc.). The Ti layer 12 preferably has a thickness of 0.5 μm. However, the thickness of the Ti layer 12 can range from 0.3 to 1.0 μm. If the layer thickness is lower than 0.3 μm then the electroplating may not be uniform. On the other hand, if the layer thickness Is greater than 1.0 μm then the Ti layer may be over-etched to an excessive degree. The Ti layer 12 will serve as a conductive (seed) layer for a subsequent electroplating process. It is advantageous to use a seed layer consisting of only one metal so as to simplify the removal of that layer at the end of the bump-formation process (a single etching step is all that is required). Titanium is the preferred material for this seed layer because it can be easily etched off the active surface 9 of the MMIC substantially without damage to the gold traces on that surface. Moreover, Ti has good adhesion to the active surface of the MMIC.

Next, as illustrated in FIG. 2B, a thick photoresist layer 13 is provided on the Ti seed layer 12 using well-known techniques, such as a spinning technique, and openings are defined in the photoresist 13 via well-known photolithography and etching techniques (a single opening 15 is shown in FIG. 2B). The openings 15 set the diameter of the bonding-bumps to be formed. The photoresist layer 13 typically has a thickness of 40 μm±3 μm, such that the combined thickness of the photoresist and the Ti seed layer 12 is close to 40 μm. As seen from FIG. 2B, the patterning steps expose a portion of the Ti seed layer 12 at the bottom of each opening 15. These exposed portions of the Ti seed layer 12 are removed by any suitable technique, such as etching using dilute hydrofluoric acid (HF) or a mixture of EDTA-H₂O₂ (EthyleneDiaminoTetraAcetic acid—hydrogen peroxide). HF is preferred because of its fast etching rate and its good selectivity (the photoresist can retain integrity during etching).

Following removal of the Ti seed layer portions that were exposed in the openings 15, contact pads P of the MMIC 10 are now exposed, as shown in FIG. 2C. Known electroplating methods can then be applied to control the plating of multiple metal layers in the opening 15 onto the contact pads P. Firstly, the relatively thick Au layer 2 is plated onto the contact pad P, followed by the very thin Ni barrier layer 3, the lower Au layer 6, intermediate Sn layer 7, and upper Au layer 8. Alternatively, other techniques can be used to deposit, for example, the upper Au layer (physical vapour deposition can conveniently be used to deposit the upper Au layer 8). The resulting structure is illustrated in FIG. 2D. As mentioned above, the dimensions of the lower Au layer 6, intermediate Sn layer 7, and upper Au layer 8 are controlled so that when the overall sandwich structure 5 is considered, the relative masses of Au and Sn therein correspond to the eutectic Au—Sn composition.

Once the electroplating is complete the photoresist layer 13 is removed, for example by a lift-off process to produce the structure illustrated in FIG. 2E. Finally, the remaining portions of the Ti seed layer are removed, once again by etching using dilute HF, or EDTA-H₂O₂. The etchant has substantially no effect on the gold traces on the active surface of the MMIC, making use of titanium as the seed layer 12 particularly advantageous. Moreover, because the seed layer 12 is removed in its entirety, the properties of the MMIC after the bonding-bumps have been formed correspond to their design values with no substantial degradation due to the bonding-bump formation process. The completed bonding-bump structure resulting from the process is as shown in FIG. 2F.

A preferred method of connecting an MMIC 10 to a substrate 20, using bonding-bumps 1 according to the preferred embodiment of the invention, will now be described with reference to FIG. 3.

As a first stage in the process, the MMIC 10 is provided with bonding-bumps 1 having the structure illustrated in FIG. 1. Preferably this is achieved using the bonding-bump fabrication process described above with reference to FIG. 2.

Referring to FIG.3, the above described bonding-bumps are used to manufacture a device comprising two circuit elements connected by said bonding-bumps. FIG. 3A schematically illustrates a first circuit element constituted by the MMIC 10 bearing on its active surface 9 two bonding-bumps 1, and a substrate 20 to which the MMIC 10 is to be connected. In FIG. 3, the height of the bonding-bumps is greatly exaggerated, to improve clarity. A dotted line 22 indicates the area of the substrate 20 facing which the MMIC 10 will be connected. On the substrate 20 there are conductive traces 23 terminating in contacts 25. In practice, the number of contact pads P, bonding-bumps 1 and contacts 25 would be greater than that shown in FIG. 3 which is simplified to ease understanding. The substrate can also be an integrated circuit.

As indicated in FIG. 3B, at the start of the preferred bump-bonding process, the active surface 9 of the MMIC 10 is turned to face the surface of the substrate 20. The MMIC 10 is positioned relative to the substrate 20 so that the bumps 1 are aligned with, and touch, the contacts 25 on the substrate. Conventional alignment processes may be used.

Heat is applied so as to cause the layers 6, 7 and 8 of the bump's soldering portion 5 to fuse and mix, forming a solder 5′ having an eutectic Au—Sn composition, as illustrated in FIG. 3C. This solder 5′ forms a bond between the contact 25 and the stem (layers 2 and 3) of the bonding-bump 1. Because of the nature and thickness of the layers 6-8 constituting the solder portion 5, it is sufficient to apply a temperature between 280° C. and 320° C. in order for a suitable bond to be formed between the bump stem 2, 3 and the contact 25. Typically, users apply this temperature for 10-20 seconds. Thus, higher temperatures, which might cause damage to the MMIC or substrate, are avoided.

Although the present invention has been described above in terms of preferred embodiments thereof, it is to be understood that numerous variations and developments can be made in the preferred embodiments without departing from the present invention as defined in the annexed claims.

For example, the present invention is not limited to techniques involving bonding-bumps formed on MMICs, the bonding bumps may be formed on other circuit elements. Furthermore, the present invention is not particularly limited with regard to the processes that can be used to form the Ti seed layer 12 on the circuit element which will bear the bonding-bump 1, or with respect to the methods used to form, pattern and remove the photoresist layer 13. Moreover, as is well-known, a variety of operating conditions can be used during electroplating of the various metal layers 2, 3, 6, 7 and 8.

The above described device has improved performances compared to the devices manufactured using techniques of the prior art. In particular, they are more reliable because their performances are both improved and more uniform. They show lower parasitic capacitance and improved low resistance. Hence, they are particularly suitable for manufacturing mobile terminals, such as mobile phones or WAP terminals, or other new sophisticated mobile terminals. The more sophisticated the terminal, the more efficient and reliable the electronic device and thus the bonding-bumps must be. Also, MMICs are integrated circuits that are particularly suitable for the use in telecommunications. Hence, mobile terminals comprising an electronic device including an MMIC connected to a substrate or an other integrated circuit, using the bonding-bumps of the invention, show both great performances and reliability.

1. An electronic device comprising a first circuit element and a second circuit element, which are connected by bonding-bumps structure, said bonding-bumps structure comprising:
a pedestal portion comprising gold and formed on a circuit element;
a barrier layer formed on the pedestal portion;
a soldering portion formed on the barrier layer, the soldering portion comprising a first layer comprising gold, a second layer comprising gold, and an intermediate layer comprising tin and located between the first and second layers;
wherein the relative masses of gold and tin in the soldering portion are such that the composition of the soldering portion corresponds to the eutectic gold-tin composition.

2. The device of claim 1, wherein the height of the pedestal portion is of the order of 30 μm.

3. The device according to claim 1, wherein the thickness of the first layer of the soldering portion is in the range 1.0 to 1.3 μm, wherein the thickness of the second layer of the soldering portion is in the range 0.7 to 0.8 μm, and wherein the thickness of the intermediate layer of the soldering portion is in the range 1.5 to 1.8 μm.

4. The according to claim 1, wherein the thickness of the first layer of the soldering portion is approximately 1.15 μm, wherein the thickness of the second layer of the soldering portion is approximately 0.75 μm, and wherein the thickness of the intermediate layer of the soldering portion is approximately 1.65 μm.

5. The device according to claim 1, wherein the height of the bonding-bump is of the order of 35 μm, and the diameter thereof is of the order of 60 μm.

6. The device according to claim 1, wherein the bump structure is formed on a monolithic microwave integrated circuit.

7. A method of forming a bonding-bump structure for a device according to claim 1, the method comprising the steps of:
(a) forming a titanium seed layer on the circuit element;
(b) removing portions of the seed layer at locations corresponding to contacts (P) on the circuit element;
(c) performing a controlled electroplating process to successively plate, at the locations corresponding to the contacts on the circuit element, the pedestal portion, the barrier layer, the first layer comprising gold, the intermediate layer comprising tin, and the second layer comprising gold;
(d) removing the remaining portions of the titanium seed layer.

8. A bonding-bump formation method according to claim 7, wherein step (b) comprises:
forming a mask layer on the titanium seed layer, and patterning the mask layer to define at least one opening; and
removing the titanium seed layer portion(s) exposed in the at least one opening.

9. A bump-bonding method of connecting a first and a second circuit element, the method comprising the steps of:
forming at least one bonding-bump according to claim 1 on a surface of the first circuit element; bringing the first and second circuit elements into a facing relationship, with the at least one bonding bump contacting the surface of the second circuit element; and
applying heat at a temperature corresponding to the gold-tin eutectic temperature.

10. The electronic device of claim 1, wherein the first circuit element is constituted by an integrated circuit and the second circuit element is constituted by a second integrated circuit or by a substrate, which are connected by bonding-bumps according to claim 9.

11. A mobile terminal comprising an electronic device as claimed in claim 10.
